(19) United States
(12) Patent Application Publication
(10) Pub. No.: US 2025/0236989 A1
(43) Pub. Date: Jul. 24, 2025

(54) SILICON CARBIDE EPITAXIAL WAFER AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventor: Tsutomu KIYOSAWA, Himeji Hyogo (JP)

(21) Appl. No.: 19/061,992

(22) Filed: Feb. 24, 2025

Related U.S. Application Data
(63) Continuation of application No. PCT/JP2024/006065, filed on Feb. 20, 2024.

(30) Foreign Application Priority Data
Jul. 31, 2023 (JP) 2023-124542

(51) Int. Cl. C30B 25/20; C30B 29/36; C30B 29/68; H01L 21/02; H10D 62/60; H10D 62/832

(52) U.S. Cl. CPC C30B 25/20; C30B 29/36; C30B 29/68; H01L 21/02378; H01L 21/02529; H10D 62/60; H10D 62/8325

(57) ABSTRACT

A method for manufacturing a silicon carbide epitaxial wafer includes forming a first silicon carbide layer on a silicon carbide wafer by epitaxially growing silicon carbide at a first growth rate of not less than 0.5 μm/h and not more than 2 μm/h to have a film thickness of not less than 1 nm and not more than 100 nm, a bump density of the first silicon carbide layer being a first density; and forming a second silicon carbide layer on the first silicon carbide layer by epitaxially growing silicon carbide at a second growth rate of greater than 2 μm/h and not more than 100 μm/h to have a film thickness of not less than 4 μm and not more than 100 μm, a bump density of the second silicon carbide layer being a second density that is less than the first density.

### CROSS-REFERENCE TO RELATED APPLICATION

This is a continuation application of International Application PCT/JP2024/006065, filed on Feb. 20, 2024; the entire contents of which are incorporated herein by reference. This application also claims priority to Japanese Application No. 2023-124542, filed on Jul. 31, 2023. The entire contents of each are incorporated herein by reference.

### FIELD

Embodiments relate to a silicon carbide epitaxial wafer and a method for manufacturing a silicon carbide epitaxial wafer.

### BACKGROUND

In recent years, semiconductor devices that use silicon carbide (SiC) are being developed. Compared to silicon (Si), SiC has a wider bandgap, and both a lower on-resistance and a higher breakdown voltage of a semiconductor device can be realized. When manufacturing a semiconductor device made of SiC, a silicon carbide epitaxial wafer is made by epitaxially growing a SiC layer that includes a prescribed concentration of impurities on a SiC wafer. However, there are problems in that many defects occur in the silicon carbide epitaxial wafer, causing discrepancies of the semiconductor device.

### BRIEF DESCRIPTION OF THE DRAWINGS

FIG. 1 is a flowchart showing a method for manufacturing a SiC epitaxial wafer according to a first embodiment;

FIG. 2 is a timing chart showing the method for manufacturing the SiC epitaxial wafer according to the first embodiment, in which the horizontal axis is time, and the vertical axis is a temperature and a silane flow rate;

FIG. 3A is a cross-sectional view showing the method for manufacturing the SiC epitaxial wafer according to the first embodiment; and FIG. 3B is a partially enlarged cross-sectional view showing region A of FIG. 3A;

FIG. 4A is a cross-sectional view showing the method for manufacturing the SiC epitaxial wafer according to the first embodiment; and FIG. 4B is a plan view of the manufacturing method;

FIG. 5 is a photomicrograph of a first SiC layer;

FIG. 6A is a figure showing AFM measurement results of a bump; FIG. 6B is a profile of a B-B cross section of FIG. 6A; FIG. 6C is a profile of a C-C cross section of FIG. 6A; FIG. 6D is a profile of a D-D cross section of FIG. 6A; and FIG. 6E is a profile of an E-E cross section of FIG. 6A;

FIG. 7A is a cross-sectional view showing the method for manufacturing the SiC epitaxial wafer according to the first embodiment; and FIG. 7B is a plan view of the manufacturing method;

FIG. 8 is a photomicrograph of a second SiC layer;

FIGS. 9A to 9C are cross-sectional views showing effects of the first embodiment;

FIG. 10A is a graph showing a relationship between a silane flow rate and a growth rate, in which the horizontal axis is the silane flow rate, and the vertical axis is the growth rate of the silicon carbide layer; and FIG. 10B is a partially enlarged view of FIG. 10A;

FIG. 11 is a cross-sectional view showing a SiC epitaxial wafer according to a second embodiment;

FIGS. 12A and 12B are cross-sectional views showing a method for manufacturing a SiC epitaxial wafer according to a comparative example; and FIG. 12C is a plan view of the manufacturing method;

FIG. 13 is a measurement result of a PL technique showing a stacking fault that occurred in the comparative example; and

FIG. 14A is a figure showing positions of stacking faults in SiC epitaxial wafers; and FIG. 14B is a graph showing numbers of the stacking faults.

### DETAILED DESCRIPTION

A method for manufacturing a silicon carbide epitaxial wafer according to an embodiment includes a process of forming a first silicon carbide layer on a silicon carbide wafer by epitaxially growing silicon carbide at a first growth rate of not less than 0.5 μm/h and not more than 2 μm/h, the first silicon carbide layer having a film thickness of not less than 1 nm and not more than 100 nm, a bump density of the first silicon carbide layer being a first density; and a process of forming a second silicon carbide layer on the first silicon carbide layer by epitaxially growing silicon carbide at a second growth rate of greater than 2 μm/h and not more than 100 μm/h, the second silicon carbide layer having a film thickness of not less than 4 μm and not more than 100 μm, a bump density of the second silicon carbide layer being a second density, the second density being less than the first density.

A silicon carbide epitaxial wafer according to an embodiment includes a silicon carbide wafer, a first silicon carbide layer, and a second silicon carbide layer; the first silicon carbide layer is located on the silicon carbide wafer and has a thickness of not less than 1 nm and not more than 100 nm; a bump density of the first silicon carbide layer is a first density; the second silicon carbide layer is located on the first silicon carbide layer and has a thickness of not less than 4 μm and not more than 100 μm; and a bump density of the second silicon carbide layer is a second density that is less than the first density.

### FIRST EMBODIMENT

The embodiment is a silicon carbide epitaxial wafer and a method for manufacturing a silicon carbide epitaxial wafer, and in particular, a method of growing an epitaxial layer made of SiC on a wafer made of SiC.

### (Method for Manufacturing)

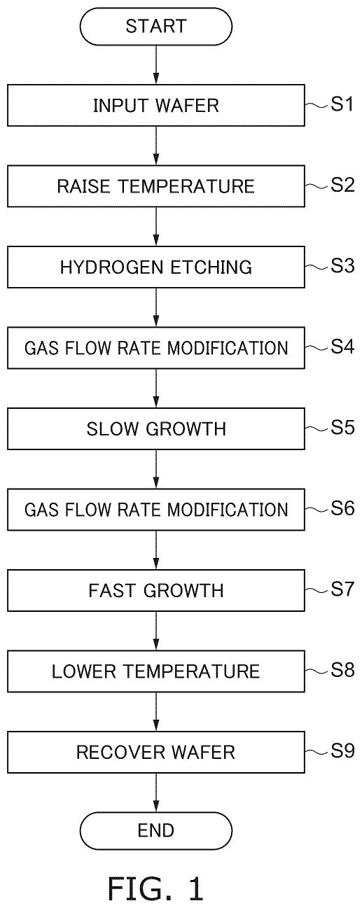

FIG. 1 is a flowchart showing a method for manufacturing a SiC epitaxial wafer according to the embodiment.

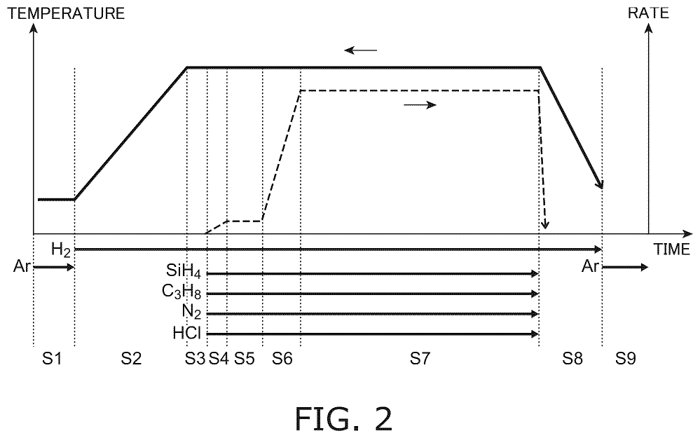

FIG. 2 is a timing chart showing the method for manufacturing the SiC epitaxial wafer according to the embodiment, in which the horizontal axis is time, and the vertical axis is a temperature and a silane flow rate.

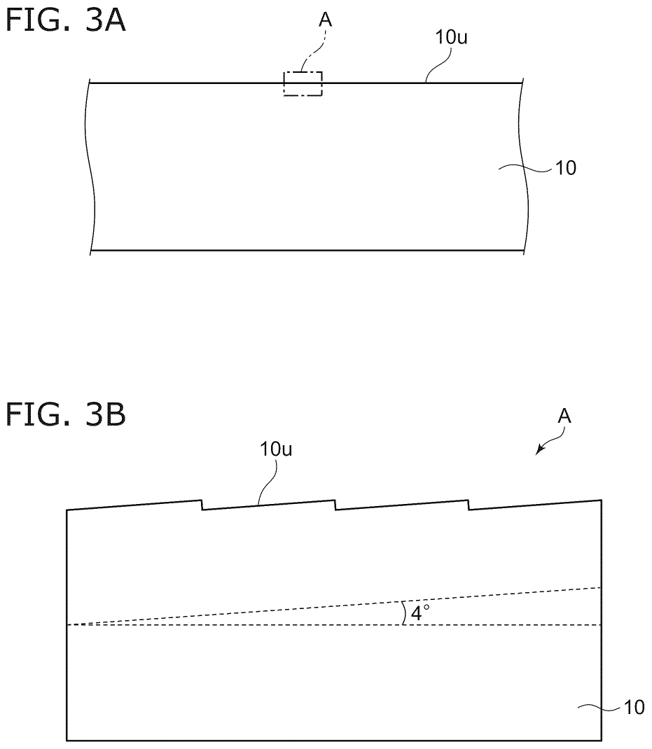

FIG. 3A is a cross-sectional view showing the method for manufacturing the SiC epitaxial wafer according to the embodiment; and FIG. 3B is a partially enlarged cross-sectional view showing region A of FIG. 3A.

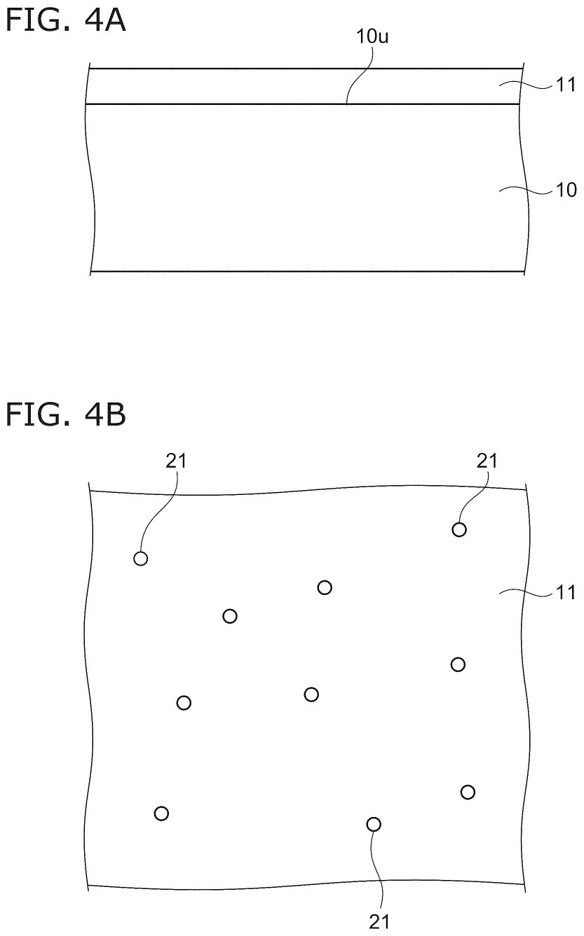

FIG. 4A is a cross-sectional view showing the method for manufacturing the SiC epitaxial wafer according to the embodiment; and FIG. 4B is a plan view of the manufacturing method.

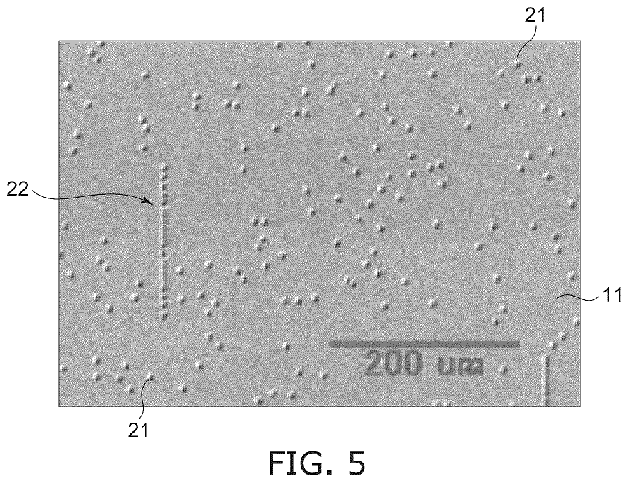

FIG. 5 is a photomicrograph of a first SiC layer.

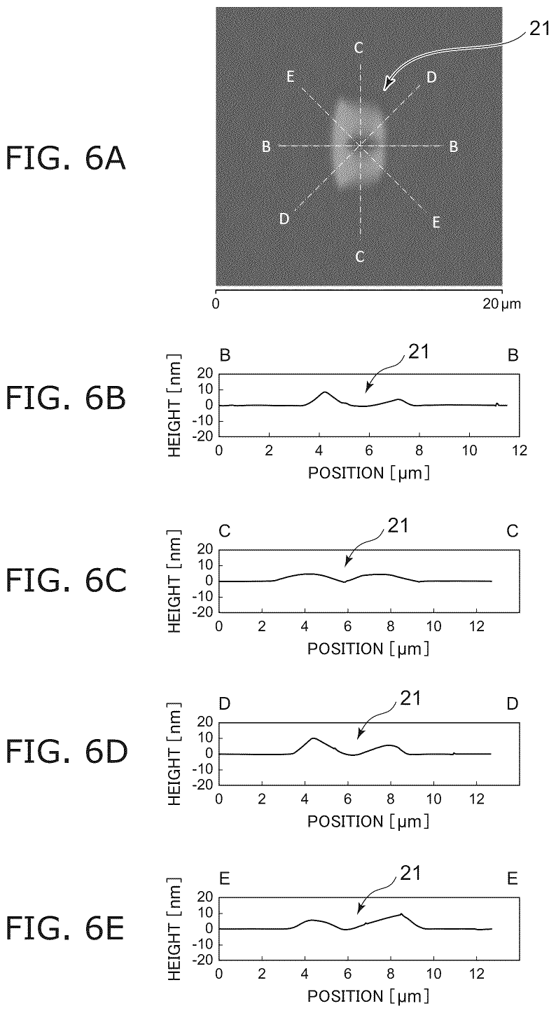

FIG. 6A is a figure showing AFM (Atomic Force Microscope: atomic force microscope) measurement results of a bump; FIG. 6B is a profile of a B-B cross section of FIG. 6A; FIG. 6C is a profile of a C-C cross section of FIG. 6A; FIG. 6D is a profile of a D-D cross section of FIG. 6A; and FIG. 6E is a profile of an E-E cross section of FIG. 6A.

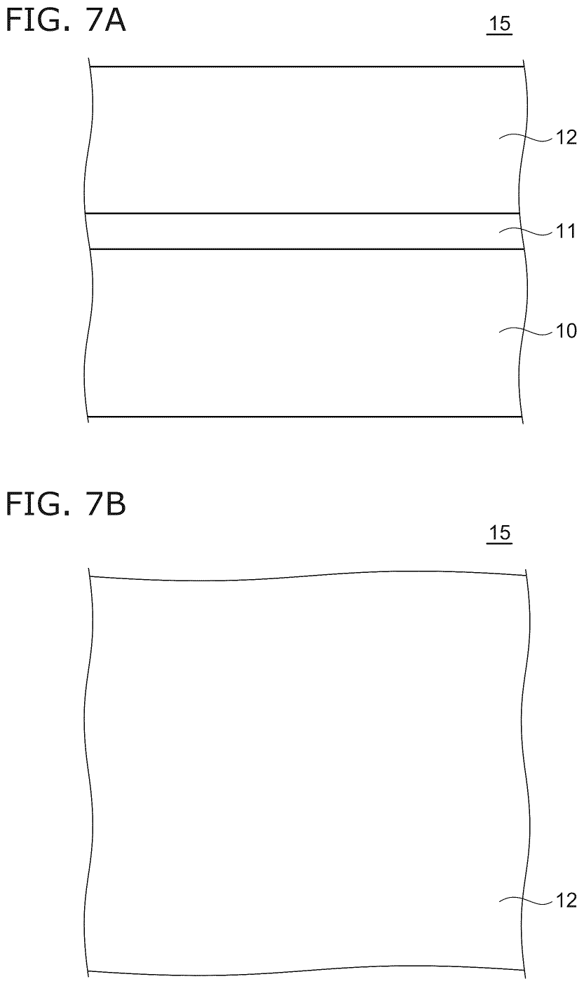

FIG. 7A is a cross-sectional view showing the method for manufacturing the SiC epitaxial wafer according to the embodiment; and FIG. 7B is a plan view of the manufacturing method.

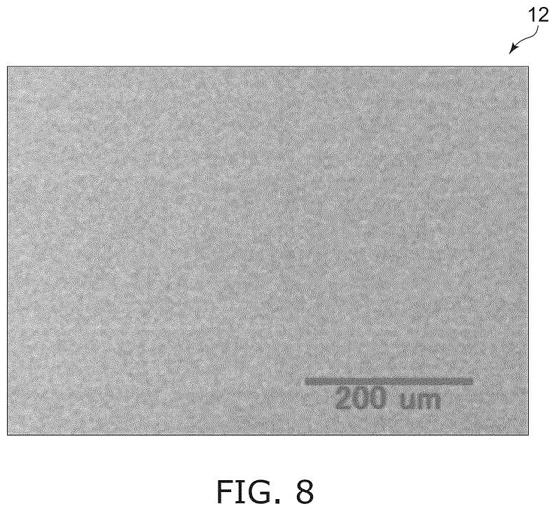

FIG. 8 is a photomicrograph of a second SiC layer.

First, a wafer input process is performed as shown in step S1 of FIGS. 1 and 2, and in FIGS. 3A and 3B.

Specifically, a SiC wafer 10 is prepared. The SiC wafer 10 is, for example, a 4H-SiC wafer having a hexagonal crystal with four periods of carbon atoms, and has a diameter of 6 inches. Also, an upper surface 10u of the SiC wafer 10 is tilted 4° with respect to the {0001} plane of the SiC wafer 10. The conductivity type of the SiC wafer 10 is an n-type; and the carrier concentration is, for example, not less than 1×10¹⁸/cm³ and not more than 1×10¹⁹/cm³.

On the other hand, an epitaxial film formation apparatus is prepared. The interior of the reactor of the epitaxial film formation apparatus is replaced with argon (Ar); and the temperature is set to, for example, room temperature. The temperature may be set to 600° C. to 1,000° C.

Then, the SiC wafer 10 is placed on a susceptor inside the reactor of the epitaxial film formation apparatus.

Continuing as shown in step S2 of FIGS. 1 and 2, a temperature raising process is performed. 5

The gas that is introduced to the reactor of the epitaxial film formation apparatus is switched from argon to hydrogen (H₂). The hydrogen flow rate may be increased continuously or in stages during at least a portion of the temperature raising process shown in step S2. Also, the temperatures of the SiC 10 wafer 10 and the interior of the reactor are raised to the SiC growth temperature. The SiC growth temperature is taken to be, for example, 1,500° C. to 1,650° C. It is favorable to set the pressure inside the reactor to a reduced-pressure atmosphere.

Then, a hydrogen etching process is performed as shown in step S3 of FIGS. 1 and 2.

The temperature is held for several minutes at the SiC growth temperature (e.g., 1,500° C. to 1,650° C.) while supplying hydrogen to the reactor. As a result, the surface of the SiC wafer 10 is etched and cleaned by hydrogen. It is favorable for the etching amount to be, for example, about several nm to several tens of nm. The hydrogen etching process also may serve as a process of stabilizing the temperature of the SiC wafer 10 and the interior of the reactor.

Then, a gas flow rate modification process is performed as shown in step S4 of FIGS. 1 and 2.

Specifically, in addition to hydrogen which is the carrier gas, silane (SiH₄) as a source gas of silicon, propane (C₃H₈) as a source gas of carbon, and nitrogen (N₂) as an n-type impurity gas used as a donor are supplied to the reactor. Hydrogen chloride (HCl) also may be supplied as a chlorine-based gas to suppress particle generation and gas phase reactions inside the reactor. However, the types of gases are not limited to the examples described above.

The flow rates of the gases are increased continuously or in stages to reach the desired flow rates of the following slow growth process. The flow rates of the gases may be immediately switched to the desired values. In such a case, the transition time until the atmosphere inside the reactor actually is switched is taken as the gas flow rate modification process.

Then, the slow growth process is performed as shown in step S5 of FIGS. 1 and 2.

By maintaining the temperature inside the reactor and the flow rates of the gases within certain ranges, SiC is epitaxially grown on the upper surface 10u of the SiC wafer 10 by, for example, thermal CVD (Chemical Vapor Deposition: chemical vapor deposition). The growth conditions at this time are set as follows.

The growth rate (a first growth rate) of SiC is set to be not less than 0.5 μm/h (micrometer per hour) and not more than 2 μm/h.

The silane (SiH₄) flow rate is set to be, for example, not less than 5 sccm and not more than 15 sccm.

The propane (C₃H₈) flow rate is set to be, for example, not less than 2 sccm and not more than 15 sccm.

The nitrogen (N₂) flow rate is selected according to the target value of the carrier concentration. The hydrogen (H₂) flow rate is set to, for example, 140 slm.

For example, the temperature is set to be not less than 1,500° C. and not more than 1,650° C.

The pressure is set to a reduced-pressure atmosphere that is less than atmospheric pressure.

The appropriate flow rates of the gases are dependent on the epitaxial film formation apparatus that is used as well as other conditions such as the temperature, the pressure, etc., and are therefore appropriately adjusted.

As a result, as shown in FIG. 4A, a first SiC layer 11 (a first silicon carbide layer) is formed on the SiC wafer 10. The thickness of the first SiC layer 11 is set to be not less than 0.001 μm (1 nm) and not more than 0.1 μm (100 nm), and favorably not less than 0.001 μm and not more than 0.02 μm (20 nm). Also, the carrier concentration is set to be, for example, not less than 1×10¹⁵/cm³ and not more than 1×10¹⁹/cm³, e.g., 1×10¹⁸/cm³.

As shown in FIG. 4B, bumps 21 are generated in the upper surface of the first SiC layer 11. The density of the bumps 21 (a first bump density) in the first SiC layer 11 is not less than 10/cm². For example, the first bump density is measured in a region that is not less than 5 mm away from the outer edge of the SiC wafer 10.

As shown in FIG. 5, the bumps 21 are interspersed on the surface of the first SiC layer 11. However, there are also cases where multiple bumps 21 are connected in one column to form a bump column 22. As shown in FIGS. 6A to 6E, the shape of each bump 21 is a substantially rectangular parallelepiped protrusion in which a recess is formed in the central portion of the upper surface of the protrusion. For example, the height of the bump 21 is not more than 10 nm; the length of the short side when viewed from above is about 4 μm; and the length of the long side is about 6 μm.

Then, a gas flow rate modification process is performed as shown in step S6 of FIGS. 1 and 2.

Specifically, the flow rates of the gases are increased continuously or in stages from the flow rates suited to the slow growth process shown in step S5 to the flow rates suited to a fast growth process shown in step S7. For example, the flow rates of the gases are increased over several seconds to several tens of seconds. The flow rates of the gases may be immediately switched. In such a case, the transition time until the atmosphere inside the reactor actually is switched is taken as the gas flow rate modification process.

Then, the fast growth process is performed as shown in step S7 of FIGS. 1 and 2.

Specifically, SiC is epitaxially grown on the first SiC layer 11 by, for example, thermal CVD. The growth conditions at this time are set to be as follows.

The growth rate (a second growth rate) of SiC is set to be greater than 2 μm/h and not more than 100 μm/h, and favorably not less than 50 μm/h and not more than 100 μm/h.

The silane (SiH₄) flow rate is set to be, for example, 360 sccm.

The propane (C₃H₈) flow rate is set to be, for example, 168 sccm.

The nitrogen (N₂) flow rate is set to be 30 sccm.

The hydrogen chloride (HCl) flow rate is set to be, for example, 4 slm.

The hydrogen (H₂) flow rate is set to be, for example, 140 slm.

The temperature is set to be, for example, not less than 1,500° C. and not more than 1,650° C.

The pressure is set to a reduced-pressure atmosphere that is less than atmospheric pressure.

As a result, a second SiC layer 12 (a second silicon carbide layer) is formed as shown in FIG. 7A. The film thickness of the second SiC layer 12 is set to be not less than 4 μm and not more than 100 μm, e.g., 10 μm. Also, the carrier concentration is set to be, for example, not less than 1×10¹⁴/cm³ and not more than 3×10¹⁶/cm³, e.g., 1×10¹⁶/cm³. For example, the second SiC layer 12 functions as a drift layer. It is sufficient to select the film thickness and the carrier concentration of the second SiC layer 12 as appropriate according to the breakdown voltage required by the semiconductor device after completion.

As shown in FIGS. 7B and 8, the density (a second bump density) of the bumps 21 in the second SiC layer 12 is less than the density (the first bump density) of the bumps 21 in the first SiC layer 11. The second bump density is not more than 5/cm², e.g., not more than 1/cm². The density of the bump column 22 is not more than 1/cm², e.g., not more than 0.5/cm².

Then, a temperature lowering process is performed as shown in step S8 of FIGS. 1 and 2.

Specifically, the temperature inside the reactor is lowered, and the supply of silane (SiH₄), propane (C₃H₈), nitrogen (N₂), and hydrogen chloride (HCl) is stopped. Hydrogen (H₂), which is the carrier gas, continues to be supplied. The temperature lowering rate can be increased thereby. The hydrogen gas flow rate may be reduced or increased. At this timing, the supply of the hydrogen gas may be stopped and switched to argon gas.

Then, a wafer recovery process is performed as shown in step S9 of FIGS. 1 and 2.

The supply of hydrogen to the reactor is stopped, and a supply of argon is started. After the atmosphere inside the reactor is switched from the hydrogen atmosphere to the argon atmosphere, the SiC wafer 10 is recovered from the reactor. The SiC epitaxial wafer 15 (a silicon carbide epitaxial wafer) in which the first SiC layer 11 and the second SiC layer 12 are formed on the SiC wafer 10 can be manufactured by the processes described above.

### (SiC Epitaxial Wafer)

The SiC wafer 10, the first SiC layer 11, and the second SiC layer 12 are included in the SiC epitaxial wafer 15 according to the embodiment as shown in FIGS. 7A, 7B, and 8. The first SiC layer 11 is located on the SiC wafer 10; and the second SiC layer 12 is located on the first SiC layer 11.

The conductivity type of the SiC wafer 10 is the n-type; and the carrier concentration is, for example, not less than 1×10¹⁸/cm³ and not more than 1×10¹⁹/cm³.

The film thickness of the first SiC layer 11 is not less than 1 nm and not more than 100 nm, and favorably not less than 1 nm and not more than 20 nm. The carrier concentration of the first SiC layer 11 is, for example, not less than 1×10¹⁵/cm³ and not more than 1×10¹⁹/cm³, e.g., 1×10¹⁸/cm³.

The bumps 21 or traces of the bumps 21 are present in the first SiC layer 11. The density (the first density) of the bumps 21 or traces of the bumps 21 is, for example, not less than 10/cm². The bump column 22 or traces of the bump column 22 may be present in the first SiC layer 11.

The film thickness of the second SiC layer 12 is not less than 4 μm and not more than 100 μm. The carrier concentration of the second SiC layer 12 is, for example, not less than 1×10¹⁴/cm³ and not more than 3×10¹⁶/cm³, e.g., 1×10¹⁶/cm³.

The density (the second density) of the bumps 21 in the second SiC layer 12 is less than the first density described above, and is, for example, not more than 5/cm², and favorably not more than 1/cm². The density of the bump column 22 is not more than 1/cm², and favorably not more than 0.5/cm². FIG. 8 shows an example in which the bumps 21 and the bump column 22 are not present within the field of view.

A method for measuring the density of the bumps 21 or traces of the bumps 21 will now be described.

Because the second SiC layer is the layer at the outermost surface, the density of the bumps 21 in the second SiC layer 12 can be calculated by detecting the uneven shape by using an optical microscope and/or AFM.

The density of the bumps 21 in the first SiC layer 11 can be calculated by detecting the uneven shape by using an optical microscope and/or AFM by using a sample that is used for setting up conditions and includes only the first SiC layer.

When, however, measuring the bump density of the first SiC layer 11 by using the SiC epitaxial wafer 15 after manufacturing, it is difficult to detect the bumps with an optical microscope and/or AFM because the first SiC layer is not the layer at the outermost surface, and the uneven shape is buried in the second SiC layer 12.

In such a case, the entire second SiC layer 12 or substantially the entire second SiC layer 12 is removed by polishing to expose or substantially expose the first SiC layer 11, and then the bump density is measured by SSRM (Scanning Spreading Resistance Microscopy: scanning spreading resistance microscopy). The bumps of the first SiC layer 11 have different growth rates and/or growth modes from the other flat locations, and so compared with the surroundings, the amount of incorporated nitrogen is different, and the electrical resistance is different; therefore, when scanning some area by SSRM, the bumps 21 are detected as regions, e.g., circular regions, of about several μm that have different electrical resistances from the surroundings. The bump density of the first SiC layer 11 can be determined by counting the number of these regions. At this time, some of the second SiC layer 12 may remain on the surface of the first SiC layer 11.

The boundary between the first SiC layer 11 and the second SiC layer 12 can be identified by measuring the n-type impurity profile by SIMS (Secondary Ionization Mass Spectrometer: secondary ion mass spectrometer).

The semiconductor device that includes SiC as a major component can be manufactured by forming any upper structures on the SiC epitaxial wafer 15 and by dicing after forming electrodes, etc. At this time, the SiC wafer 10 and the first SiC layer 11 may be included in a buffer layer of the semiconductor device; and the second SiC layer 12 may be included in a drift layer of the semiconductor device.

### (Effects)

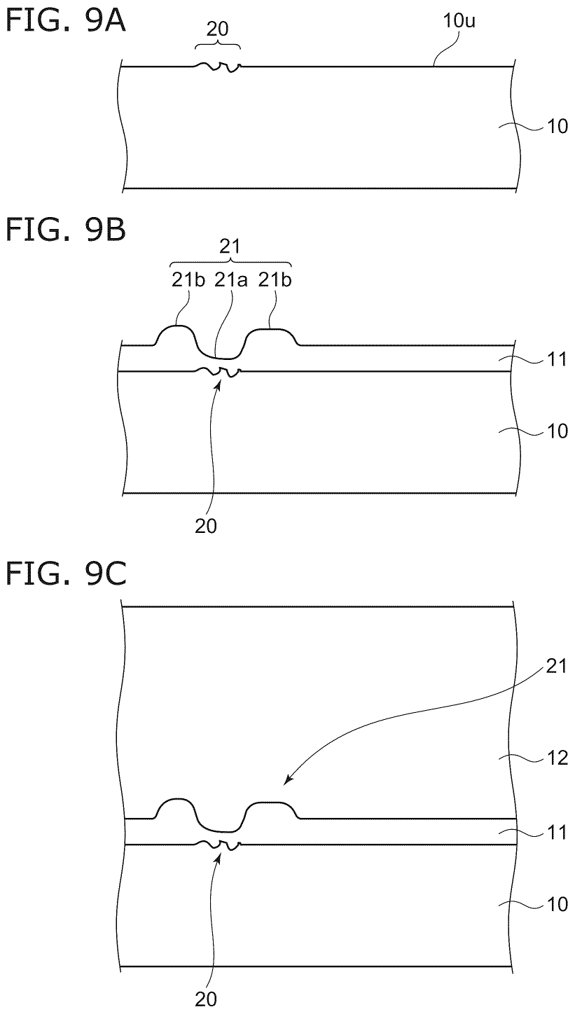

FIGS. 9A to 9C are cross-sectional views showing effects of the embodiment.

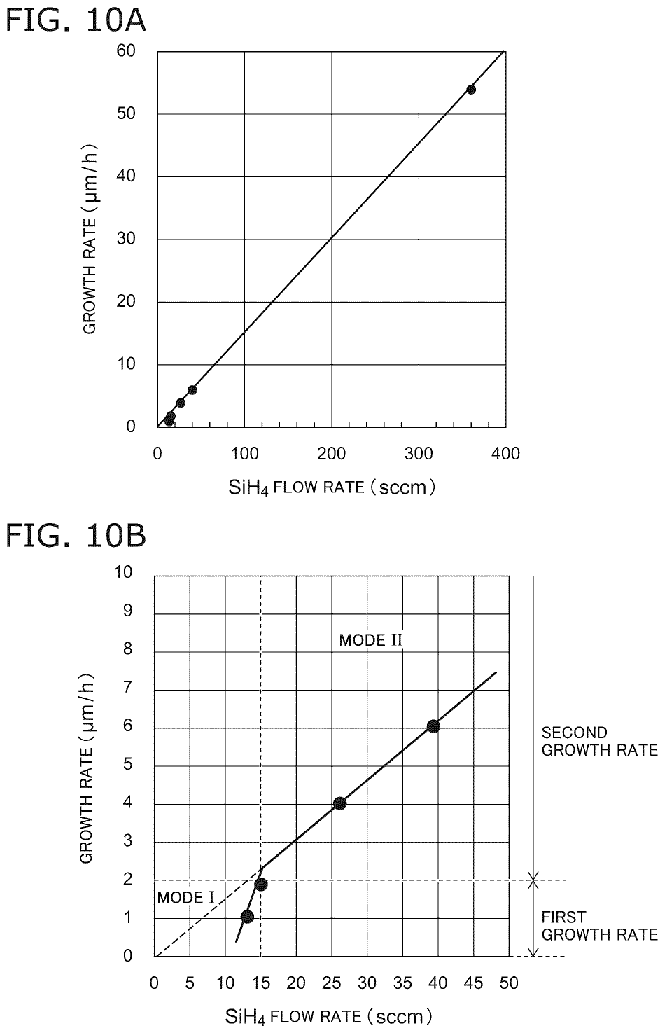

FIG. 10A is a graph showing a relationship between a silane flow rate and a growth rate, in which the horizontal axis is the silane flow rate, and the vertical axis is the growth rate of the silicon carbide layer; and FIG. 10B is a partially enlarged view of FIG. 10A.

Similarly to the embodiment, the measurement results shown in FIGS. 10A and 10B are the results of epitaxially growing a SiC layer on a SiC wafer by supplying silane and propane as source gases, nitrogen as an impurity gas, hydrogen chloride as a cleaning gas, and hydrogen as a carrier gas.

As shown in FIG. 9A, defects 20 are unavoidably present in the upper surface 10u of the SiC wafer 10. The defects 20 are defects in SiC wafer 10 itself such as dislocation and crystal defects, etc., and defects caused by processes such as fine scratches caused by damage when patterning, etc.

In the embodiment, as shown in FIG. 9B, the first SiC layer 11 is formed on the upper surface 10u of the SiC wafer 10 at the first growth rate, i.e., a rate of not less than 0.5 μm/h and not more than 2 μm/h.

As shown in FIGS. 10A and 10B, the epitaxial growth of SiC includes mode II in which the silane flow rate and the growth rate are substantially proportional, and mode I in which the growth rate is less than the silane flow rate compared with mode II. The growth rate that is used as the boundary between mode I and mode II is 2 μm/h. In other words, the SiC epitaxial growth proceeds in mode I if the growth rate is not more than 2 μm/h, and the SiC epitaxial growth proceeds in mode II if the growth rate is greater than 2 μm/h. In FIG. 10, the flow rate of propane (C₃H₈) also is modified so that the C/Si ratio (the value of the ratio of C to Si included in the supplied source gas) is maintained at 1.4.

The rate of the epitaxial growth is determined by the sum of an adsorption component in which atoms are adsorbed, and a desorption component in which atoms desorb after being once adsorbed. The desorption component also includes the effect of etching by hydrogen gas. In mode I, the desorption component is dominant compared with mode II; and the growth rate with respect to the silane flow rate is low compared with mode II. The repeated adsorption and desorption of atoms on the SiC wafer 10 repairs the defects 20.

It is estimated that a recess 21a is formed in the upper surface of the first SiC layer 11 because atoms that adsorbed to the top of the defect 20 are easily desorbed. Also, it is estimated that a protrusion 21b is formed around the recess 21a because the atoms that desorb from the defect 20 easily adsorb around the recess 21a. The bump 21 is formed of the recess 21a and the protrusion 21b. Thus, by forming the first SiC layer 11 in mode I, at least a portion of the defects 20 is repaired; and the bumps 21 are formed.

Then, as shown in FIG. 9C, SiC is deposited on the first SiC layer 11 at a second growth rate, which is a rate that is greater than 2 μm/h and not more than 100 μm/h. As a result, the second SiC layer 12 is formed in mode II. In mode II, epitaxial growth proceeds under conditions such that the adsorption of atoms is more dominant than desorption. Therefore, the bumps 21 that are generated in the surface of the first SiC layer 11 are buried in the second SiC layer 12. As a result, the density of the bumps 21 is reduced at the upper surface of the second SiC layer 12 compared with the first SiC layer 11.

In the embodiment, at least a portion of the defects 20 of the SiC wafer 10 are repaired by forming the first SiC layer 11 at the first growth rate. As a result, the occurrence of stacking faults caused by the defects 20 in the first SiC layer 11 and the second SiC layer 12 can be suppressed. For example, the stacking fault density can be 10/cm² or less.

A stacking fault is a portion in which a crystal structure that is different from the surroundings is formed. For example, this portion becomes a stacking fault when the SiC wafer 10 is a 4H-SiC wafer, the offset angle is 4°, and a layer that has a different crystal structure grows with the defect 20 as a starting point. When a stacking fault is included in the semiconductor device after completion, there is a possibility that the leakage current of the semiconductor device may increase, and the long-term reliability may degrade.

Thus, according to the embodiment, the occurrence of stacking faults can be suppressed. Also, according to the embodiment, triangular defects and carrot defects also can be reduced. As a result, a silicon carbide epitaxial wafer with fewer defects can be manufactured.

Also, according to the embodiment, the first growth rate is set to be not less than 0.5 μm/h. As a result, when forming the first SiC layer 11, a certain throughput can be ensured, and the cost can be reduced.

Furthermore, according to the embodiment, the film thickness of the first SiC layer 11 is set to be not less than 1 nm. The defects 20 can be effectively repaired thereby. On the other hand, when the first SiC layer 11 is formed to be too thick, the unevenness of the bumps 21 becomes large, and bump columns 22 are generated. The bumps 21 and the bump columns 22 that have too much unevenness may be difficult to bury by subsequently forming the second SiC layer 12.

When many bumps 21 remain in the second SiC layer 12, there is a possibility that the leakage current of the semiconductor device may increase, and the reliability of the oxide film may degrade. Also, when the first SiC layer 11 is formed to be too thick, step bunching easily occurs. In the embodiment, by setting the film thickness of the first SiC layer 11 to be not more than 100 nm, the excessive growth of the bumps 21 and/or the generation of the bump columns 22 can be suppressed, and step bunching also can be suppressed. More favorably, the film thickness of the first SiC layer 11 is set to be not more than 20 nm.

Furthermore, according to the embodiment, the second growth rate when forming the second SiC layer 12 is greater than 2 μm/h. As a result, mode II can be realized, and the bumps 21 can be buried. As the second growth rate increases, the bumps 21 can be effectively buried, and the productivity of the SiC epitaxial wafer is increased. It is therefore favorable for the second growth rate to be not less than 50 μm/h. On the other hand, according to the embodiment, the second growth rate is set to be not more than 100 μm/h. As a result, the second SiC layer 12 can be epitaxially grown reliably.

### SECOND EMBODIMENT

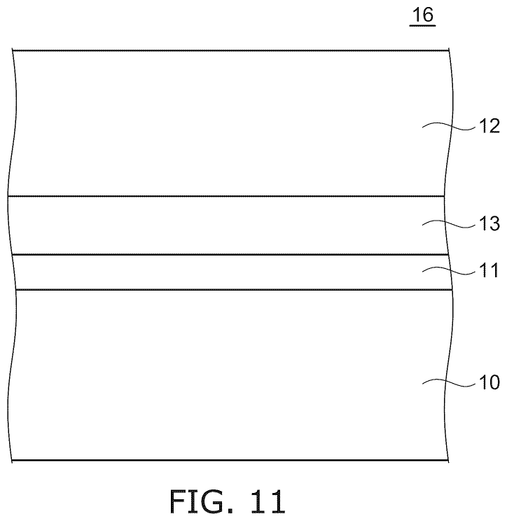

FIG. 11 is a cross-sectional view showing a SiC epitaxial wafer according to the embodiment.

In the embodiment, as shown in FIG. 11, a third SiC layer 13 (a third silicon carbide layer) is formed between the first SiC layer 11 and the second SiC layer 12.

The third SiC layer 13 is formed by epitaxially growing SiC on the first SiC layer 11 at a higher growth rate than the first growth rate. The growth rate of the third SiC layer 13 may be equal to the growth rate of the second SiC layer 12, or may be a rate that is between the growth rate of the first SiC layer 11 and the growth rate of the second SiC layer 12. The growth conditions of the third SiC layer 13 are, for example, as follows.

The SiC growth rate is set to be greater than 2 μm/h and not more than 100 μm/h, and favorably not less than 5 μm/h and not more than 100 μm/h.

The flow rates of silane (SiH₄), propane (C₃H₈), and nitrogen (N₂) are appropriately adjusted.

For example, the temperature is set to be not less than 1,500° C. and not more than 1,650° C.

The pressure is set to be a reduced-pressure atmosphere that is less than atmospheric pressure.

The film thickness of the third SiC layer 13 is set to be not less than 0.1 μm and not more than 20 μm, e.g., 1 μm. For example, the carrier concentration of the third SiC layer 13 is set to be greater than the carrier concentration of the second SiC layer 12. For example, the carrier concentration of the third SiC layer 13 is set to be not less than 1×10¹⁷/cm³ and not more than 2×10¹⁸/cm³, e.g., 1×10¹⁸/cm³. Then, the second SiC layer 12 is formed on the third SiC layer 13. The SiC epitaxial wafer 16 is manufactured thereby.

By setting the carrier concentration of the first SiC layer 11 and the carrier concentration of the third SiC layer 13 to be greater than the carrier concentration of the second SiC layer 12, the SiC wafer 10, the first SiC layer 11, and the third SiC layer 13 can be included in a buffer layer of the semiconductor device after completion; and the second SiC layer 12 can be included in a drift layer of the semiconductor device. By increasing the carrier concentration of the buffer layer, the extension of the depletion layer to the substrate during the device operation can be suppressed, or BPDs (Basal Plane Dislocations: basal plane dislocations) expanding into stacking faults due to the buffer layer acting as a recombination enhancement layer can be suppressed.

When measuring the bump density of the first SiC layer 11 by using the SiC epitaxial wafer 16, the second SiC layer 12 and the third SiC layer 13 are removed by polishing to expose the first SiC layer 11, and then the bump density is measured using the method described in the first embodiment. At this time, some of the third SiC layer 13 may remain on the surface of the first SiC layer 11.

The boundary between the first SiC layer 11 and the third SiC layer 13 and the boundary between the third SiC layer 13 and the second SiC layer 12 can be identified by measuring the profile of the n-type impurity by SIMS.

According to the embodiment, by forming the third SiC layer 13 between the first SiC layer 11 and the second SiC layer 12, a buffer layer that has the film thickness required by the semiconductor device after completion can be formed efficiently. Also, by using mode II to form the third SiC layer 13, the unevenness of the bumps 21 can be somewhat reduced without increasing the unevenness of the bumps 21 generated in the first SiC layer 11 and without newly forming the bump column 22. The manufacturing method, the configuration, and the effects according to the embodiment other than those described above are similar to those of the first embodiment.

### COMPARATIVE EXAMPLE

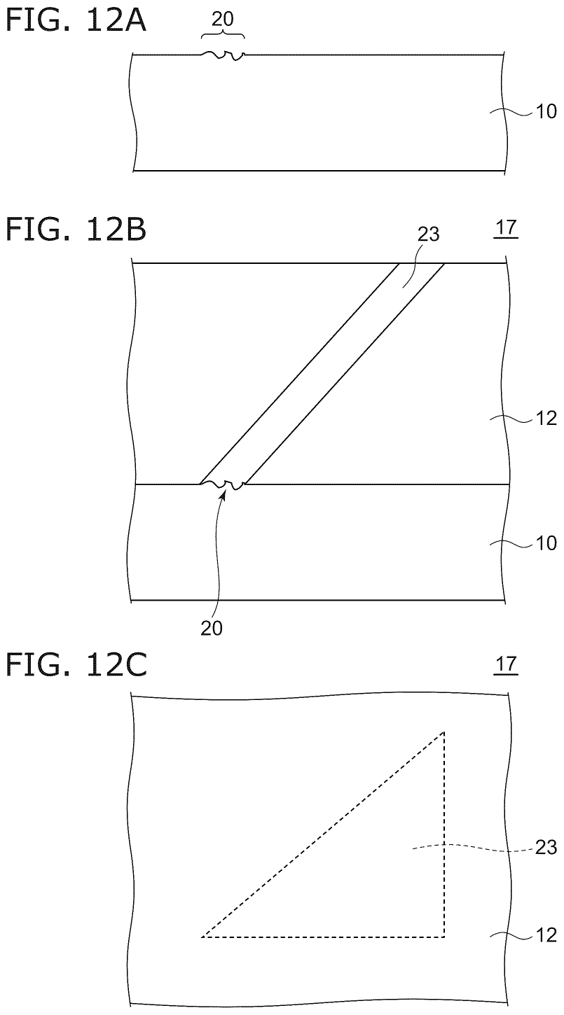

FIGS. 12A and 12B are cross-sectional views showing a method for manufacturing a SiC epitaxial wafer according to the comparative example; and FIG. 12C is a plan view of the manufacturing method.

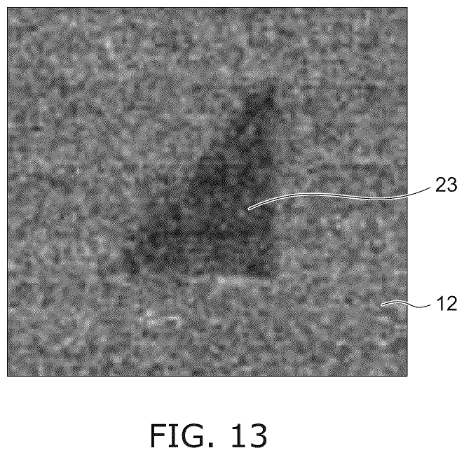

FIG. 13 is a measurement result of a PL (PhotoLuminescence: photoluminescence) technique showing a stacking fault that occurred in the comparative example.

The SiC wafer 10 is prepared as shown in FIG. 12A. The SiC wafer 10 unavoidably includes the defect 20.

According to the comparative example as shown in FIG. 12B, the second SiC layer 12 is formed directly on the SiC wafer 10 without forming the first SiC layer 11. Similarly to the first embodiment, the second SiC layer 12 is formed at the second growth rate. The SiC epitaxial wafer 17 according to the comparative example is manufactured thereby.

In the SiC epitaxial wafer 17, a stacking fault 23 is formed inside the second SiC layer 12 with the defect 20 as a starting point. As described above, the stacking fault 23 is a portion that has a different crystal structure from the surroundings.

As shown in FIGS. 12C and 13, the shape of the stacking fault 23 is triangular when viewed from above; and the position of one vertex corresponds to the position of the defect 20. It is difficult to observe the stacking fault with an optical microscope or a SEM (Scanning Electron Microscope: scanning electron microscope). For example, the stacking fault can be observed using the PL technique.

### TEST EXAMPLES

Test examples that compare the first embodiment and comparative examples will now be described.

In the test examples, six SiC wafers 10 were taken from the same ingot. The diameters of the SiC wafers 10 were 6 inches.

For three SiC wafers 10, the first SiC layer 11 and the second SiC layer 12 were formed by the method described in the first embodiment to manufacture the SiC epitaxial wafer 15. The first growth rate when forming the first SiC layer 11 was set to 1 μm/h. For the other three SiC wafers 10, the second SiC layer 12 was formed by the method described in the comparative example to manufacture the SiC epitaxial wafer 17.

Then, the PL technique was used to detect stacking faults in the three SiC epitaxial wafers 15 and the three SiC epitaxial wafers 17. The stacking faults that were detected were mapped on the wafer and counted.

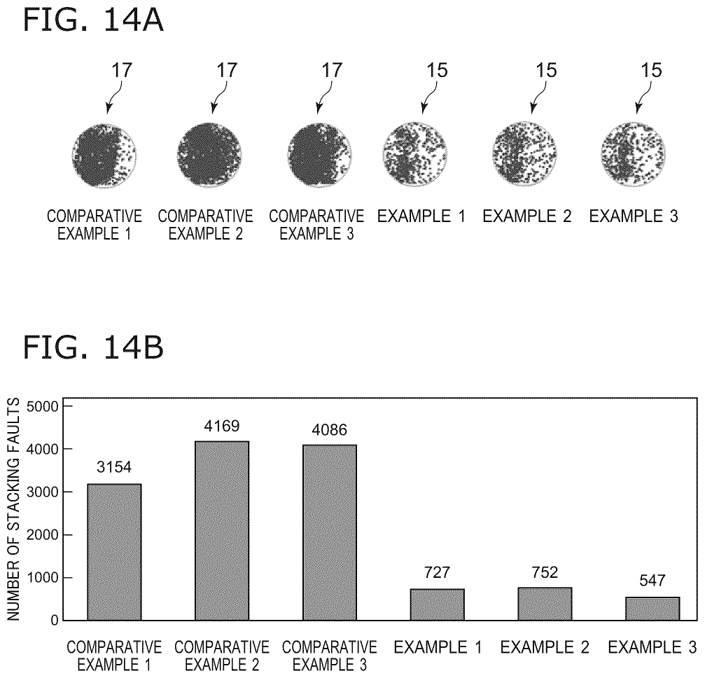

FIG. 14A is a figure showing positions of stacking faults in the SiC epitaxial wafers; and FIG. 14B is a graph showing numbers of the stacking faults.

In FIGS. 14A and 14B, Examples 1 to 3 are the SiC epitaxial wafers 15 manufactured by the method according to the first embodiment; and Comparative Examples 1 to 3 are the SiC epitaxial wafers 17 manufactured by the method according to the comparative example.

FIG. 14B also shows the number of stacking faults detected.

As shown in FIGS. 14A and 14B, according to the first embodiment, the number of stacking faults could be reduced to be not more than 18% compared to the comparative examples.

According to the embodiments above, a silicon carbide epitaxial wafer and a method for manufacturing a silicon carbide epitaxial wafer can be realized in which defects can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments herein may be made without departing from the spirit of the inventions.

The accompanying claims and their equivalents are intended to cover such forms or modifications as would fall within the scope and spirit of the inventions.

The invention includes the following aspects.

### Note 1

A method for manufacturing a silicon carbide epitaxial wafer, the method comprising:
forming a first silicon carbide layer on a silicon carbide wafer by epitaxially growing silicon carbide at a first growth rate of not less than 0.5 μm/h and not more than 2 μm/h, the first silicon carbide layer having a film thickness of not less than 1 nm and not more than 100 nm, a bump density of the first silicon carbide layer being a first density; and
forming a second silicon carbide layer on the first silicon carbide layer by epitaxially growing silicon carbide at a second growth rate of greater than 2 μm/h and not more than 100 μm/h, the second silicon carbide layer having a film thickness of not less than 4 μm and not more than 100 μm, a bump density of the second silicon carbide layer being a second density, the second density being less than the first density.

### Note 2

The method for manufacturing the silicon carbide epitaxial wafer according to Note 1, wherein
the first density is not less than 10/cm², and
the second density is not more than 5/cm².

### Note 3

The method for manufacturing the silicon carbide epitaxial wafer according to Note 1 or 2, wherein the film thickness of the first silicon carbide layer is not more than 20 nm.

### Note 4

The method for manufacturing the silicon carbide epitaxial wafer according to any one of Notes 1 to 3, wherein
the second growth rate is not less than 50 μm/h.

### Note 5

The method for manufacturing the silicon carbide epitaxial wafer according to any one of Notes 1 to 4, further comprising:
forming a third silicon carbide layer on the first silicon carbide layer by epitaxially growing silicon carbide at a higher growth rate than the first growth rate, the third silicon carbide layer having a film thickness of not less than 0.1 μm and not more than 20 μm,
the second silicon carbide layer being formed on the third silicon carbide layer.

### Note 6

The method for manufacturing the silicon carbide epitaxial wafer according to Note 5, wherein
a carrier concentration of the first silicon carbide layer and a carrier concentration of the third silicon carbide layer are set to be greater than a carrier concentration of the second silicon carbide layer.

### Note 7

A silicon carbide epitaxial wafer, comprising:
a silicon carbide wafer;
a first silicon carbide layer located on the silicon carbide wafer, the first silicon carbide layer having a thickness of not less than 1 nm and not more than 100 nm, a bump density of the first silicon carbide layer being a first density; and
a second silicon carbide layer located on the first silicon carbide layer, the second silicon carbide layer having a thickness of not less than 4 μm and not more than 100 μm, a bump density of the second silicon carbide layer being a second density, the second density being less than the first density.

### Note 8

The silicon carbide epitaxial wafer according to Note 7, wherein
the first density is not less than 10/cm², and
the second density is not more than 5/cm².

### Note 9

The silicon carbide epitaxial wafer according to Note 7 or 8, further comprising:
a third silicon carbide layer located between the first silicon carbide layer and the second silicon carbide layer,
the third silicon carbide layer having a film thickness of not less than 0.1 μm and not more than 20 μm,
a carrier concentration of the first silicon carbide layer and a carrier concentration of the third silicon carbide layer being greater than a carrier concentration of the second silicon carbide layer.

What is claimed is:

1. A method for manufacturing a silicon carbide epitaxial wafer, the method comprising:
forming a first silicon carbide layer on a silicon carbide wafer by epitaxially growing silicon carbide at a first growth rate of not less than 0.5 μm/h and not more than 2 μm/h, the first silicon carbide layer having a film thickness of not less than 1 nm and not more than 100 nm, a bump density of the first silicon carbide layer being a first density; and
forming a second silicon carbide layer on the first silicon carbide layer by epitaxially growing silicon carbide at a second growth rate of greater than 2 μm/h and not more than 100 μm/h, the second silicon carbide layer having a film thickness of not less than 4 μm and not more than 100 μm, a bump density of the second silicon carbide layer being a second density, the second density being less than the first density.

2. The method for manufacturing the silicon carbide epitaxial wafer according to claim 1, wherein
the first density is not less than 10/cm², and
the second density is not more than 5/cm².

3. The method for manufacturing the silicon carbide epitaxial wafer according to claim 1, wherein
the film thickness of the first silicon carbide layer is not more than 20 nm.

4. The method for manufacturing the silicon carbide epitaxial wafer according to claim 1, wherein
the second growth rate is not less than 50 μm/h.

5. The method for manufacturing the silicon carbide epitaxial wafer according to claim 1, further comprising:
forming a third silicon carbide layer on the first silicon carbide layer by epitaxially growing silicon carbide at a higher growth rate than the first growth rate, the third silicon carbide layer having a film thickness of not less than 0.1 μm and not more than 20 μm,
the second silicon carbide layer being formed on the third silicon carbide layer.

6. The method for manufacturing the silicon carbide epitaxial wafer according to claim 5, wherein
a carrier concentration of the first silicon carbide layer and a carrier concentration of the third silicon carbide layer are set to be greater than a carrier concentration of the second silicon carbide layer.

7. A silicon carbide epitaxial wafer, comprising:
a silicon carbide wafer;
a first silicon carbide layer located on the silicon carbide wafer, the first silicon carbide layer having a thickness of not less than 1 nm and not more than 100 nm, a bump density of the first silicon carbide layer being a first density; and
a second silicon carbide layer located on the first silicon carbide layer, the second silicon carbide layer having a thickness of not less than 4 μm and not more than 100 μm, a bump density of the second silicon carbide layer being a second density, the second density being less than the first density.

8. The silicon carbide epitaxial wafer according to claim 7, wherein
the first density is not less than 10/cm², and
the second density is not more than 5/cm².

9. The silicon carbide epitaxial wafer according to claim 7, further comprising:
a third silicon carbide layer located between the first silicon carbide layer and the second silicon carbide layer,
the third silicon carbide layer having a film thickness of not less than 0.1 μm and not more than 20 μm,
a carrier concentration of the first silicon carbide layer and a carrier concentration of the third silicon carbide layer being greater than a carrier concentration of the second silicon carbide layer.
